(19) United States
(12) Patent Application Publication
(10) Pub. No.: US 2009/0200613 A1
(43) Pub. Date: Aug. 13, 2009

(54) SEMICONDUCTOR DEVICE

(75) Inventors: Keisuke Uemura, Chiba-shi (JP); Jun Osanai, Chiba-shi (JP)

Correspondence Address: Brinks Hofer Gilson & Lione/Seiko Instruments Inc., P.O. Box 10395, Chicago, IL, 60611, US

(73) Assignee: Seiko Instruments Inc., Chiba-shi (JP)

(21) Appl. No.: 12/363,989

(22) Filed: Feb. 2, 2009

(30) Foreign Application Priority Data
Feb. 7, 2008 (JP) JP2008-027246

(51) Int. Cl. H01L 29/78

(52) U.S. Cl. 257/368; 257/E29.255

(57) ABSTRACT

A transistor having a perpendicular channel direction and a transistor having a parallel channel direction are combined to cancel out stress-induced change in a characteristic value, providing a semiconductor device whose shift in characteristic value is small. Consequently, a channel that runs in a direction perpendicular to one side of a semiconductor chip is formed in one transistor (10), whereas a channel that runs in a direction parallel to the one side is formed in another transistor (11).

### RELATED APPLICATIONS

This application claims priority under 35 U.S.C. §119 to Japanese Patent Application No. JP2008-027246 filed on Feb. 7, 2008, the entire content of which is hereby incorporated by reference.

### 1. TECHNICAL FIELD

The present invention relates to a semiconductor device with high precision, and a method of manufacturing the same.

### 2. BACKGROUND ART

A further enhancement to the precision of power ICs, such as voltage detectors (VDs), voltage regulators (VRs), and lithium battery protection ICs, is required in recent years. Variances, which occur in a wafer manufacturing process (wafer process), are usually smoothed by trimming of fuses made of polysilicon with a laser or the like in a wafer testing process (assembly and testing process) to obtain a uniform characteristic value in order to accomplish high precision.

Even in a chip that has achieved high precision in this way a change in characteristics during a packaging process or a mounting process of a chip to a print board may still cause failure to meet product specifications in some cases. A change in characteristics of an element induced by thermal stress can be a cause of the change in characteristics along the packaging process or the board mounting process. Specifically, application of a stress to the semiconductor chip during these processes or a change in the application of the stress caused by applied heat, results in a change in resistance of a polysilicon resistor and a change in threshold voltage of a transistor.

JP 2000-124343 A, for example, discloses an invention for preventing these changes by adjusting the characteristics of a semiconductor product after the mounting to a print board. However, the cited invention shows a complicated process and it would be difficult to put into practice from the standpoint of cost. A simpler and more cost-effective method for stabilizing the characteristic value is required.

Problems to be solved by the invention of the present application are shown as is follows:

A change occurs in a characteristic of a high-precision semiconductor product during the assembling of the semiconductor product. A stress-induced change in the characteristics of an element is, as mentioned above, suspected to be a cause. For example, stress is applied to the semiconductor chip from a sealing resin and the resistance and characteristics of the element change through the piezo-resistance effect. In recent years, packaging a semiconductor chip in a small-sized package has become popular to meet requests for parts size reduction, and the thickness of semiconductor chips are becoming thinner in response. A thinner semiconductor chip is more severely distorted even from the same magnitude of stress, causing an apprehension of a greater change in the characteristics. The amount of the change in the characteristics is, in the case of the overcharge detection voltage of a lithium battery protection IC, for example, merely about a few mV, but this amount of change cannot be ignored in a high precision product.

On the other hand high precision semiconductor products accomplish high precision by utilizing identical characteristics between paired transistors. For instance, a current mirror circuit operates to make currents in two current paths equal to each other by utilizing the fact that the same amount of current flows in each of the paired P-channel MOS transistors. It is usually desirable to place the paired transistors as close as possible to each other or adjacent to each other if possible, within the semiconductor product, in order that the characteristics of the paired transistors do not differ from each other significantly. Aligning the channel directions of the paired transistors as well contributes to stabilizing the characteristics.

Application of a stress to such semiconductor products, however, causes a change in the characteristic value. In this case, if the applied stress is uneven between the paired transistors, that is, if different levels of stress are applied to paired transistors, the change in the characteristic value of one transistor differs from the change in the characteristic value of the other transistor.

### SUMMARY OF THE INVENTION

An object of the present invention is to provide a semiconductor device capable of reducing such a stress-induced change in characteristic value. In order to solve the above-mentioned problems, the present invention employs the following means.

A semiconductor device is provided in which a change in characteristics is reduced by utilizing an angular dependency of a stress to an angle formed by a carrier traveling direction to cancel out stress-induced change.

Another means is to provide a semiconductor device in which application of stress is uniformed between paired transistors to reduce a change in characteristics.

With the present invention, a change in characteristic value during assembling of the semiconductor device can be reduced compared to the prior art, and the semiconductor device with even higher precision can be provided.

### BRIEF DESCRIPTION OF THE DRAWINGS

FIG. 1 is a schematic diagram of a combined semiconductor circuit used in a semiconductor device according to the present invention;

FIG. 2 is a schematic diagram of a cross-shape semiconductor circuit used in the semiconductor device according to the present invention;

FIG. 3 is a schematic diagram of a circular semiconductor circuit used in the semiconductor device according to the present invention; and

FIG. 4 is a schematic diagram of a semiconductor circuit with intersected wiring lines used in the semiconductor device according to the present invention.

### DETAILED DESCRIPTION OF THE PREFERRED EMBODIMENTS

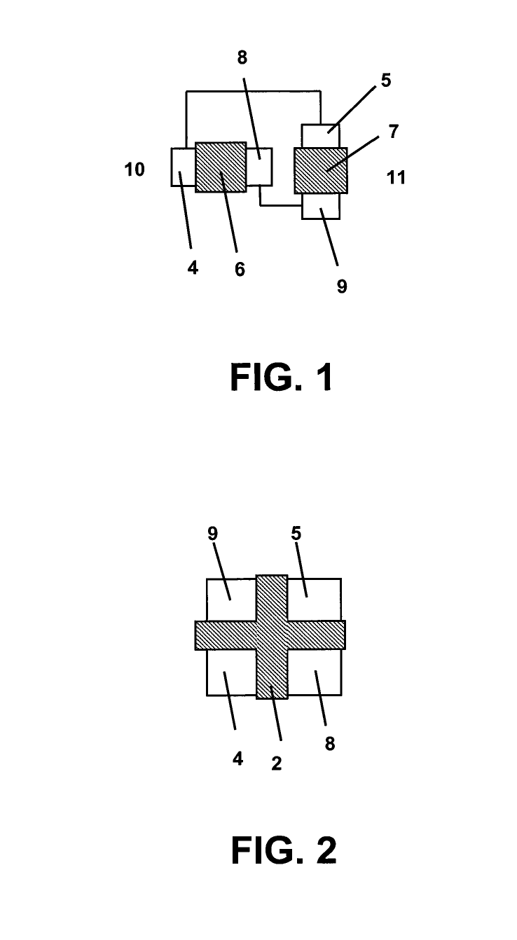

Embodiments of the present invention are described below with reference to FIGS. 1 to 4.

A semiconductor element is known to show a shift in resistance or in electric current value as a result of a change in carrier mobility caused by stress applied upon assembling through the piezo-resistance effect. In a MOS transistor, in particular, a mobility change causes a prominent shift in the mutual conductance Gm. Then, the change in characteristic value induced by stress upon assembling becomes too large to be ignored in a current mirror circuit and other circuits built on the premise that the Gm value between paired transistors is constant. Taking the current mirror circuit as an example here, a change in a characteristic value of the circuit occurs when an amount of shift in Gm, ΔGm, differs between paired transistors.

Accordingly, changes in characteristic value of paired transistors, here, shifts in Gm value, which have great influence over the circuit's characteristic value, are made equal to each other, to thereby cancel out changes in characteristic value of paired transistors. Measuring an amount of stress applied to a chip upon assembling or predicting through simulation, the layout is determined in a manner that makes the magnitude of stress applied to the element, as well as the angle formed by the stress and the channel, equal between the paired transistors. This equalizes shifts between the paired transistors, and ultimately reduces the characteristics change that occurs in assembling.

### First Embodiment

The piezo-resistance effect of a silicon semiconductor exhibits plane orientation dependency. A method of reducing a shift by utilizing the plane orientation dependency is employed here. The hole mobility in the <110> direction, for example, is known to change in opposite manners when the channel is perpendicular to the direction of stress and when parallel to the direction of the stress. This effect is utilized in designing a layout for forming one transistor such that channels are at right angles with each other, instead of keeping to one channel formation direction. Accordingly, the direction of one shift with respect to stress is opposite to the direction of another shift with respect to the stress, and hence the shifts are canceled out. A change in characteristic value is reduced as a result.

FIG. 1 is a schematic diagram of a first embodiment of the present invention. A first transistor 10 includes a first source electrode 4, a first gate electrode 6, and a first drain electrode 8, as well as a gate insulating film and a channel region, which are right below the first gate electrode. A second transistor 11 includes a second source electrode 5, a second gate electrode 7, and a second drain electrode 9, as well as a gate insulating film and a channel region, which are right below the second gate electrode. The first transistor 10 and the second transistor 11 are connected to each other through their source electrodes. The first transistor 10 and the second transistor 11 are arranged such that the channel angle of one transistor is larger or smaller than the channel angle of the other transistor by 90°. In the transistor 10, a channel running in a direction perpendicular to one side of a semiconductor chip is formed whereas in the other transistor 11, a channel is formed in a direction parallel to this side of the chip. By thus combining a transistor that has a perpendicular channel direction and a transistor that has a parallel channel direction, a change in characteristic value of the former transistor and a change in characteristic value of the latter transistor, which occur when the transistors are in operation, can be canceled out.

In an actual circuit, a plurality of transistors having varying channel angles are arranged to form more pairs in this manner. A high-precision circuit where the change in characteristic value is small is thus obtained.

### Second Embodiment

FIG. 2 is a schematic diagram of a second embodiment of the present invention. A gate insulating film and a gate electrode 2 are formed into a cross pattern so as to cover a channel region. Of four regions partitioned by the channel region, source regions and source electrodes 4 and 5 are placed in two opposing regions, whereas drain regions and drain electrodes 8 and 9 are placed in the remaining two opposing regions. The channel region is in the cross pattern, and hence orthogonal components thereof cancel out changes in characteristic value, which occur when transistors are in operation.

### Third Embodiment

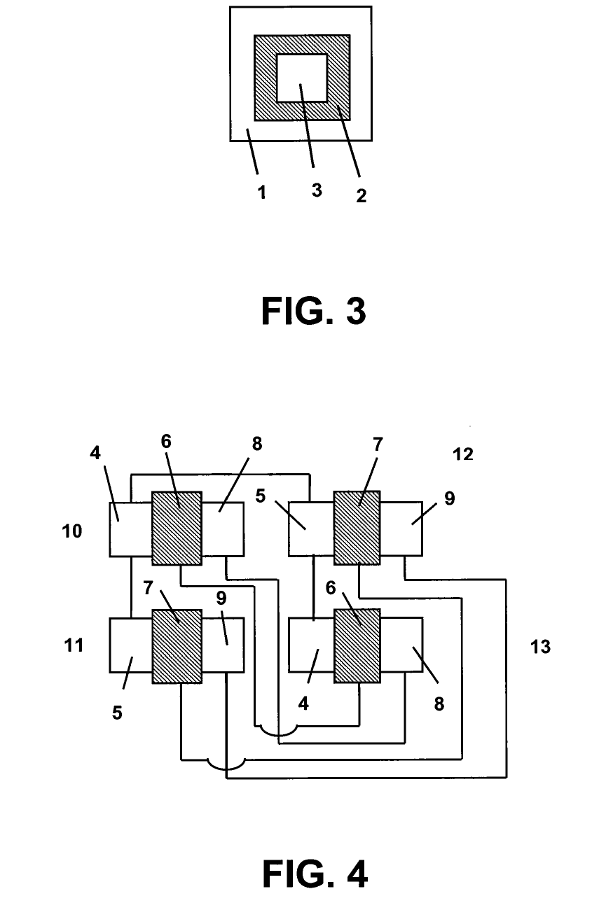

FIG. 3 is a schematic diagram of a third embodiment of the present invention. A drain region 3 is placed inside a belt-like channel region which forms a rectangular pattern. A source region 1 is placed outside the channel region. A gate insulating film and a gate electrode are formed so as to cover the channel region. When transistors are in operation, channels are formed in four directions and act to cancel out changes in characteristic value of one another. While FIG. 3 takes as an example the belt-like channel region in the rectangular pattern, the channel region may form a ring pattern instead. In this case, a drain region is placed inside the ring-like channel region, a source region is placed outside the channel region, and a gate insulating film and a gate electrode are formed so as to cover the channel region. Channels are formed in all directions when transistors are put in operation, and changes in characteristic value are thus canceled out more efficiently.

### Fourth Embodiment

As another embodiment, transistors are arranged in a manner illustrated in FIG. 4 (common-centroid layout). First transistors 10 and 13 each include a first source electrode 4, a first gate electrode 6, and a first drain electrode 8, as well as a gate insulating film and a channel region, which are right below the first gate electrode. The first transistors 10 and 13 are placed diagonally to each other. The gate electrodes and drain electrodes of the first transistors 10 and 13 are connected to each other. Second transistors 11 and 12 each include a second source electrode 5, a second gate electrode 7, and a second drain electrode 9, as well as a gate insulating film and a channel region, which are right below the second gate electrode. The second transistors 11 and 12 are placed diagonally to each other. The gate electrodes and drain electrodes of the second transistors 11 and 12 are connected to each other. The source electrodes of the four transistors are connected in series, from the transistor 11 to the transistor 10, then the transistor 12, and lastly the transistor 13.

In this arrangement, there are two or more angles each formed by a channel and stress which are similar to those in the above-mentioned embodiments, except that the angles here are not orthogonal to one another. However, arranging transistors diagonally in an intersecting manner reduces the shift in the end. This arrangement has an effect of giving equal average values of stress applied to paired transistors when there is stress distribution within the semiconductor chip. The effect ultimately reduces the change in characteristic value.

1. A semiconductor device comprising:
a semiconductor substrate; and
a pair of MOS transistors operating as a single transistor, the pair of MOS transistor comprising:
a plurality of channel regions provided on the semiconductor substrate, and having a plurality of channel directions that are arranged orthogonally to one another; and
a plurality of source regions and a plurality of drain regions facing each other across the channel region, and connected to each other.

2. A semiconductor device according to claim 1; wherein the channel region of the MOS transistors is cross-shaped, and
wherein, of four regions partitioned of the cross-shaped channel region, two source regions are arranged to face each other and two drain regions are arranged in remaining regions to face each other.

3. A semiconductor device according to claim 1; wherein the MOS transistors each include:
a belt-like, rectangular pattern channel region of a first conductivity type formed on the semiconductor substrate of the first conductivity;
a drain region of a second conductivity type formed in an area enclosed by the belt-like, rectangular pattern channel region;
a source region of the second conductivity type formed in an area outside the channel region of first conductivity type; a gate insulating film formed on the belt-like, rectangular pattern channel region; and
a gate electrode formed on the gate insulating film.

4. A semiconductor device according to claim 1; wherein the MOS transistors each include:
a ring-like channel region of a first conductivity type formed on the semiconductor substrate of the first conductivity;
a drain region of a second conductivity type formed in an area that is enclosed by the ring-like channel region; a source region of the second conductivity type formed in an area outside the channel region of the first conductivity type;
a gate insulating film formed on the ring-like channel region; and
a gate electrode formed on the gate insulating film.

5. A semiconductor device comprising:
a pair of MOS transistors operating as a single transistor, the pair of MOS transistor comprising:
a first transistor including a first channel region which forms a channel in a direction perpendicular to one side of a semiconductor chip; and
a second transistor including a second channel region which forms a channel in a direction parallel to the one side of the semiconductor chip, the first transistor and the second transistor having a plurality of source regions and a plurality of drain regions which face each other across the first channel region and the second channel region, and are connected to each other.

6. A semiconductor device comprising two pairs of MOS transistors including four MOS transistors having the same channel direction arranged on a semiconductor substrate; wherein each of drain electrodes and gate electrodes of each two diagonally placed MOS transistors of the four MOS transistors are connected.
